(19) United States
(12) Patent Application Publication
(10) Pub. No.: US 2025/0253158 A1
(43) Pub. Date: Aug. 7, 2025

(54) DRY DEPOSITION OF EXTREME ULTRAVIOLET (EUV) UNDERLAYER FOR LITHOGRAPHY AND PATTERNING

(71) Applicant: Applied Materials, Inc., Santa Clara, CA (US)

(72) Inventors: HUIXIONG DAI, San Jose, CA (US); KHOI PHAN, San Jose, CA (US); BO XIE, San Jose, CA (US); RUI LU, Sunnyvale, CA (US); CHI-I LANG, Cupertino, CA (US); KENT ZHAO, Santa Clara, CA (US)

(21) Appl. No.: 18/433,210

(22) Filed: Feb. 5, 2024

(51) Int. Cl. H01L 21/311; H01L 21/02

(52) U.S. Cl. CPC H01L 21/31144; H01L 21/02126; H01L 21/02274; H01L 21/0228

(57) ABSTRACT

Embodiments disclosed herein comprise a method for patterning a stack. In an embodiment, the method comprises providing a substrate with a hardmask layer over the substrate, and depositing an underlayer over the hardmask layer with a dry deposition process, where the underlayer comprises silicon, carbon, oxygen, and hydrogen. In an embodiment, the method further comprises forming a resist layer over the underlayer, exposing and developing the resist layer to form a pattern in the resist layer, and transferring the pattern into the underlayer and the hardmask layer with an etch process.

### BACKGROUND

### 1) Field

Embodiments relate to the field of semiconductor manufacturing and, in particular, apparatuses and methods for improving extreme ultraviolet (EUV) lithography through the use of a SiCHO underlayer that is deposited with a dry deposition process.

### 2) Description of Related Art

Advances in semiconductor manufacturing are driving minimum feature sizes (e.g., a critical dimension (CD)) smaller and smaller. For example, feature sizes at advanced processing nodes may be 14 nm or smaller, 7 nm or smaller, or 3 nm or smaller. Extreme ultraviolet (EUV) lithography is one option for fabricating features with such small dimensions. While EUV lithography is capable of forming small features, EUV lithography still has some limitations that may be addressed.

One limitation is that existing EUV resist systems suffer from low absorption of the EUV electromagnetic radiation. Accordingly, large doses of the EUV electromagnetic radiation are needed in order to implement the solubility switch in the resist layer that allows for the development and patterning of the EUV resist. Typically, the resolution of the resist and other metrics (e.g., line edge roughness (LER), line width roughness (LWR), local critical dimension uniformity (LCDU)), are improved with higher doses as well. As such, reducing the dose of the EUV resist development process can generate patterning issues.

### SUMMARY

Embodiments disclosed herein comprise a method for patterning a stack. In an embodiment, the method comprises providing a substrate with a hardmask layer over the substrate, and depositing an underlayer over the hardmask layer with a dry deposition process, where the underlayer comprises silicon, carbon, oxygen, and hydrogen. In an embodiment, the method further comprises forming a resist layer over the underlayer, exposing and developing the resist layer to form a pattern in the resist layer, and transferring the pattern into the underlayer and the hardmask layer with an etch process.

Embodiments disclosed herein may also comprise a method for forming an underlayer for extreme ultraviolet (EUV) lithography. In an embodiment, the method comprises providing a substrate within a chamber, and flowing a precursor comprising silicon and carbon into the chamber. In an embodiment, the method further comprises initiating a plasma in the chamber, and depositing the underlayer on the substrate. In an embodiment, the underlayer comprises silicon, carbon, oxygen, and hydrogen.

Embodiments disclosed herein may also comprise an underlayer. In an embodiment, the underlayer comprises a dielectric material with a top surface and a bottom surface. In an embodiment, the dielectric material comprises silicon, carbon, hydrogen, and oxygen. In an embodiment, two or more sub-layers are within the dielectric material, and the two or more sub-layers comprise different concentrations of one or more of silicon, carbon hydrogen, and oxygen.

### BRIEF DESCRIPTION OF THE DRAWINGS

FIG. 1 is a cross-sectional illustration of a semiconductor device with a patterning stack that comprises a dielectric underlayer between an extreme ultraviolet (EUV) resist layer and a hardmask layer, in accordance with an embodiment.

FIG. 2A is a cross-sectional illustration of a patterning stack with a dielectric underlayer with an interface layer with a hardmask, in accordance with an embodiment.

FIG. 2B is a cross-sectional illustration of a patterning stack with a dielectric underlayer with a first interface layer on a hardmask and a second interface layer contacting the EUV resist, in accordance with an embodiment.

FIG. 2C is a cross-sectional illustration of a patterning stack with a dielectric underlayer that comprises a graded composition through a thickness of the underlayer, in accordance with an embodiment.

FIG. 3 is a process flow diagram of a process for patterning a substrate with an EUV lithography process that includes a dielectric underlayer below the EUV resist, in accordance with an embodiment.

FIGS. 4A-4D are cross-sectional illustrations depicting a process for forming an EUV patterning stack with a dielectric underlayer and patterning the EUV patterning stack, in accordance with an embodiment.

FIGS. 5A-5C are chemical structures of various ring type precursors used to form the dielectric underlayer with a dry deposition process, in accordance with an embodiment.

FIGS. 6A-6D are chemical structures of various linear precursors used to form the dielectric underlayer with a dry deposition process, in accordance with an embodiment.

FIGS. 7A and 7B are chemical structures of Si—O—Si based precursors used to form the dielectric underlayer with a dry deposition process, in accordance with an embodiment.

FIGS. 8A-8E are chemical structures of Si—C—Si based precursors used to form the dielectric underlayer with a dry deposition process, in accordance with an embodiment.

FIG. 9 is a cross-sectional illustration of a semiconductor processing chamber that can be used to deposit the underlayer for an EUV resist patterning stack, in accordance with an embodiment.

FIG. 10 is a process flow diagram of a process for depositing a SiCOH underlayer with a dry deposition process, in accordance with an embodiment.

FIG. 11 illustrates a block diagram of an exemplary computer system that may be used in conjunction with a processing tool, in accordance with an embodiment.

### DETAILED DESCRIPTION

Systems described herein include systems and methods for improving extreme ultraviolet (EUV) lithography through the use of a SiCHO underlayer that is deposited with a dry deposition process. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, EUV resists suffer from poor absorption. To account for the poor absorption, larger doses of EUV electromagnetic radiation are needed in order to enable the solubility switch in the EUV resist. Increasing the dose requires longer exposure times, and therefore, lower throughput. This increases the cost of EUV lithography.

One solution to improve the processing of EUV resists is to provide an underlayer below the EUV resist. The underlayer may be provided between a bottom surface of the EUV resist and a top surface of the hardmask. The purpose of the underlayer is to improve the absorption of electrons into the EUV resist. Ideally, this can allow for a reduction in dose, while still maintaining improved patterning performance with respect to different measureable parameters (e.g., line edge roughness (LER), line width roughness (LWR), local critical dimension uniformity (LCDU), etc.).

However, existing underlayer materials are deposited with a wet process. For example, spin-coating is commonly used to dispense the underlayer. The use of wet processes to deposit the underlayer has several limitations. One drawback is that the underlayer will have a substantially uniform material composition through an entire thickness of the underlayer. This prevents the ability to tune the underlayer in order to provide enhanced performance. For example, development of the spin-coated underlayer will need to make tradeoffs with respect to chemical compositions that enhance electron transfer into the EUV resist from the underlayer with chemical compositions that improve adhesion between layers. Another drawback is that wet processes limit how thin the underlayer can be made. For example, spin-coating processes may be limited to thicknesses of 100 nm or greater. However, thinner underlayers may be beneficial for pattern performance and transfer into the underlying layers.

Accordingly, embodiments disclosed herein include an EUV patterning stack that comprises a dielectric underlayer that is formed with a dry deposition process. The use of a dry deposition process (e.g., chemical vapor deposition (CVD), plasma-enhanced CVD (PE-CVD), atomic layer deposition (ALD), plasma-enhanced ALD (PE-ALD), etc.) provides a greater degree of freedom in order to engineer the underlayer.

In one embodiment, dry deposition processes allow for non-uniform material composition through a thickness of the underlayer. This allows for several design options that may be beneficial to the EUV lithography process. For example, a bottom surface of the underlayer may be tuned for improved adhesion with a hardmask, and an upper portion of the underlayer may be tuned for improved EUV absorption in the overlying resist layer. In some instances, the underlayer may have a graded material composition through a thickness of the underlayer.

Non-uniform compositions can be controlled through the control of one or more processing parameters during the dry deposition process. For example, flow rates of one or more precursors may be modulated. Changes to one or more of pressure, temperature, RF bias, or the like may also be used in order to adjust the material composition of the underlayer and/or a structure (e.g., microstructure, porosity, density, etc.) of the underlayer.

Embodiments disclosed herein may also allow for the generation of thin underlayer films. The underlayers disclosed herein may have thicknesses that are approximately 50 nm or less, approximately 25 nm or less, or approximately 10 nm or less. As used herein, “approximately” may refer to a range of values within ten percent of the stated value. For example, “approximately 10 nm” may refer to a range of values between 9 nm and 11 nm.

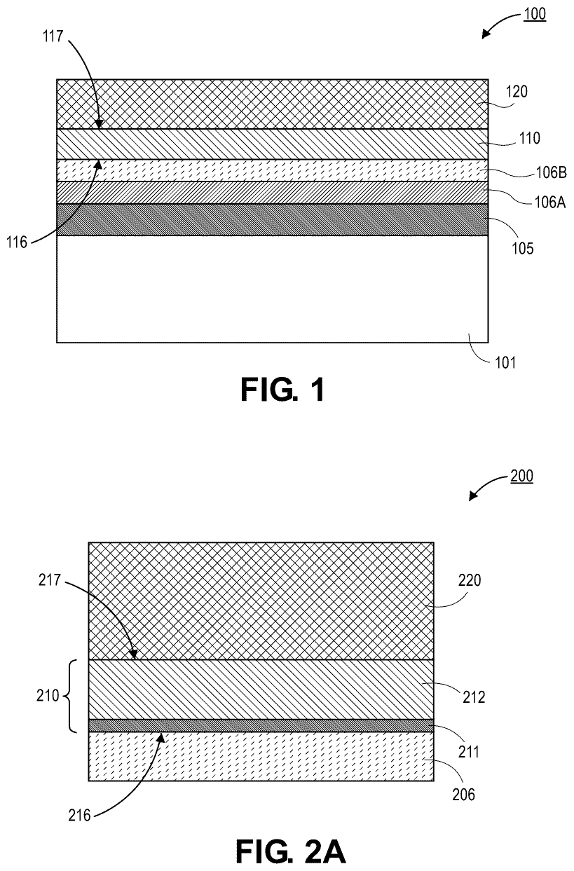

Referring now to FIG. 1, a cross-sectional illustration of a portion of a patterning stack 100 is shown, in accordance with an embodiment. In an embodiment, the patterning stack 100 may comprise a substrate 101. The substrate 101 may be a semiconductor substrate, such as a silicon substrate. Though, other materials may also be used for the substrate 101. The substrate 101 may have any suitable form factor. For example, the substrate 101 may be a wafer with a 300 mm diameter, a 450 mm diameter, or the like.

In an embodiment, a device layer 105 may be provided on the substrate 101. The device layer 105 may comprise active and/or passive electrical structures (not shown). For example, the device layer 105 may include transistor structures that are electrically coupled to each other to provide electrical circuitry or the like. The device layer 105 may be considered as being a front end of line (FEOL) layer, or a back end of line (BEOL) layer.

In an embodiment, one or more hardmask layers 106 may be provided over the device layer 105. In FIG. 1, a pair of hardmask layers 106A and 106B are shown. The two hardmask layers 106A and 106B may have different material compositions and/or thicknesses. Though, in other embodiments, the hardmask layer 106A may be similar to the hardmask layer 106B. The hardmask layers 106A and 106B may comprise any suitable material composition. For example, the hardmask layers 106A and 106B may comprise metal, carbon, silicon, nitrogen, and/or the like. In a particular embodiment, the hardmask layers 106A and/or 106B may comprise a metallic nitride, an amorphous carbon layer, or the like.

In an embodiment, an underlayer 110 may be provided over the hardmask layer 106B. The underlayer 110 may comprise a dielectric material. In some instances, the dielectric material is a low-k dielectric material (e.g., a material with a dielectric constant that is less than approximately 3.5). The underlayer 110 may be a material that is chosen in order to improve patterning performance of an overlying resist layer 120. The presence of an underlayer 110 may be helpful when the resist layer 120 is an EUV resist layer that suffers from low absorption of EUV radiation.

In order to combat the low absorption, the underlayer 110 may provide one or more different mechanisms to improve the exposure and development of the resist layer 120. In one embodiment, the underlayer 110 may release structures (e.g., chemical structures, branches, and/or elements) upon EUV exposure, and these structures can diffuse into the overlying EUV resist layer 120. The added structures can aid in the absorption of the EUV radiation and provide enhanced contrast in the resist layer 120. In another embodiment, the underlayer 110 may improve contrast in the resist layer 120 through the injection of secondary electrons from the underlayer 110 into the resist layer 120. The underlayer 110 may release the secondary electrons upon absorption of EUV radiation. The secondary electrons may diffuse into the resist layer 120 where they can participate in the chemical reaction driving the solubility switch in the resist layer 120.

In a particular embodiment, the underlayer 110 may comprise a dielectric that comprises silicon, carbon, hydrogen, and oxygen. For example, the underlayer 110 may be considered as a SiCHO material layer. The underlayer 110 may be deposited with a dry deposition process. As such, the material composition and/or material properties may be non-uniform through a thickness of the underlayer 110, as will be described in greater detail below. In an embodiment, the underlayer 110 may also be deposited to a minimal thickness compared to wet processes (e.g., spin coating). For example, a thickness of the underlayer 110 between the bottom surface 116 and the top surface 117 may be approximately 50 nm or less, approximately 25 nm or less, or approximately 10 nm or less.

In an embodiment, the dry deposition process used to form the underlayer 110 may comprise CVD, PE-CVD, ALD, PE-ALD, or the like. Processing chambers suitable for such deposition processes are described in greater detail below. Generally, the dry deposition process may include the flowing of one or more precursor gasses into the chamber in order to drive reactions that deposit the underlayer 110 onto the hardmask 106. Control of one or more deposition processing parameters can be used to alter material composition and/or structure through a thickness of the underlayer 110.

In an embodiment, the overlying resist layer 120 is any suitable EUV resist material. For example, the resist layer 120 may comprise a metal-oxide resist material, such as a tin-oxide resist layer 120. The resist layer 120 may also include a chemically amplified resist (CAR) system. In some embodiments, the resist layer 120 may also be deposited with a dry deposition process. In such an embodiment, both the underlayer 110 and the resist layer 120 may be deposited within a single tool.

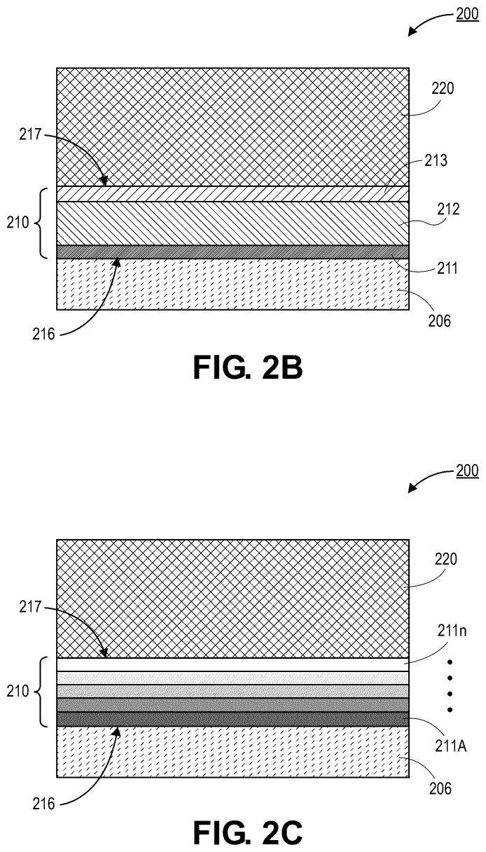

Referring now to FIGS. 2A-2C, a series of cross-sectional illustrations depicting a portion of a patterning stack 200 is shown, in accordance with an embodiment. In FIGS. 2A-20, the patterning stack 200 is shown starting with a hardmask layer 206. It is to be appreciated that a device layer and a substrate may be provided below the hardmask layer 206. Further, while a single hardmask layer 206 is shown, other embodiments may include two or more hardmask layers 206, similar to the embodiment shown in FIG. 1.

Referring now to FIG. 2A, a cross-sectional illustration of a patterning stack 200 is shown, in accordance with an embodiment. The patterning stack 200 may comprise a hardmask 206 and an underlayer 210 over the hardmask 206. For example, a bottom surface 216 of the underlayer 210 may contact the hardmask 206. In an embodiment a resist layer 220 may be provided over the underlayer 210. The resist layer 220 may contact a top surface 217 of the underlayer 210. In an embodiment, the hardmask 206 and the resist layer 220 may be similar to the hardmasks 106 and the resist layer 120 described in greater detail herein.

In an embodiment, the underlayer 210 may comprise a plurality of sub-layers, such as a first sub-layer 211 and a second sub-layer 212. The sub-layers 211 and 212 may be tuned to optimize different metrics in order to improve the overall effectiveness of the underlayer 210. For example, the first sub-layer 211 may contact the hardmask 206. As such, the adhesion properties between the first sub-layer 211 and the hardmask 206 may be optimized to improve bonding between the first sub-layer 211 and the hardmask 206. The second sub-layer 212 may be optimized to improve secondary electron generation and/or chemical species diffusion up into the overlying resist layer 220.

In order to satisfy these different property requirements, a material composition of the first sub-layer 211 may be different than a material composition of the second sub-layer 212. In one embodiment, the difference in material composition may include different percentages of the same elements. For example, the first sub-layer 211 and the second sub-layer 212 may both comprise SiCHO, but the first sub-layer 211 may have a different concentration of silicon than the second sub-layer 212. In other embodiments, the first sub-layer 211 and the second sub-layer 212 may comprise different elements as well. The ability to provide compositional differences between layers is enabled through the use of a dry deposition process, as will be described in greater detail herein.

Also, structural differences between the first sub-layer 211 and the second sub-layer 212 may be present. For example, structural differences such as density, chemical bonding structure, and/or the like may be provided between the first sub-layer 211 and the second sub-layer 212. The structural differences may be controlled through the use of different deposition parameters, such as pressure, temperature, flow rates of one or more precursors, bias potential, and/or the like. That is, there are multiple knobs that can be changed throughout a single deposition process in order to provide different structures in the first sub-layer 211 and the second sub-layer 212.

In an embodiment, the first sub-layer 211 and the second sub-layer 212 may each have any suitable thickness. In the embodiment shown in FIG. 2A, the first sub-layer 211 is thinner than the second sub-layer 212. Though, the first sub-layer 211 may be a similar thickness to the second sub-layer 212, or the first sub-layer 211 may be thicker than the second sub-layer 212.

Referring now to FIG. 2B, a cross-sectional illustration of a patterning stack 200 is shown, in accordance with an embodiment. The patterning stack 200 may comprise a hardmask 206 and an underlayer 210 over the hardmask 206. For example, a bottom surface 216 of the underlayer 210 may contact the hardmask 206. In an embodiment a resist layer 220 may be provided over the underlayer 210. The resist layer 220 may contact a top surface 217 of the underlayer 210. In an embodiment, the hardmask 206 and the resist layer 220 may be similar to the hardmasks 106 and the resist layer 120 described in greater detail herein.

In an embodiment, the underlayer 210 may include a plurality of sub-layers. For example, the underlayer 210 may comprise a first sub-layer 211, a second sub-layer 212, and a third sub-layer 213. In an embodiment, the different sub-layers 211-213 may include different material compositions and/or different material properties. For example, the first sub-layer 211 may be optimized to improve adhesion between the underlayer 210 and the hardmask 206, and the third sub-layer 213 may be optimized to improve adhesion between the underlayer 210 and the resist layer 220. The second sub-layer 212 may be optimize to provide increased production of secondary electrons and/or to enhance the release of chemical structures that can diffuse into the resist layer 220 to improve the solubility switch of the resist layer 220.

In an embodiment, all of the sub-layers 211-213 may have different material compositions. In one embodiment, the difference in material composition may include different percentages of the same elements. For example, the first sub-layer 211, the second sub-layer 212, and the third sub-layer 213 may all comprise SiCHO, but the sub-layers 211-213 may each have a different concentration of silicon. In other embodiments, one or more of the sub-layers 211-213 may comprise elements that are not present in other sub-layers 211-213. The ability to provide compositional differences between layers is enabled through the use of a dry deposition process, as will be described in greater detail herein.

Also, structural differences between the sub-layers 211-213 may be present. For example, structural differences such as density, chemical bonding structure, and/or the like may be provided between two or more of the sub-layers 211-213. The structural differences may be controlled through the use of different deposition parameters, such as pressure, temperature, flow rates of one or more precursors, bias potential, and/or the like.

In an embodiment, the sub-layers 211-213 may each have any suitable thickness. In the embodiment shown in FIG. 2B, the first sub-layer 211 and the third sub-layer 213 are thinner than the second sub-layer 212. Though, all of the sub-layers 211-213 may be similar in thickness, two of the sub-layers 211-213 may be similar in thickness, or all sub-layers 211-213 may have substantially different thicknesses.

Referring now to FIG. 2C, a cross-sectional illustration of a patterning stack 200 is shown, in accordance with an embodiment. The patterning stack 200 may comprise a hardmask 206 and an underlayer 210 over the hardmask 206. For example, a bottom surface 216 of the underlayer 210 may contact the hardmask 206. In an embodiment a resist layer 220 may be provided over the underlayer 210. The resist layer 220 may contact a top surface 217 of the underlayer 210. In an embodiment, the hardmask 206 and the resist layer 220 may be similar to the hardmasks 106 and the resist layer 120 described in greater detail herein.

In an embodiment, the underlayer 210 may comprise a plurality of sub-layers. For example, underlayer 210 comprises sub-layers 211A-211n. More particularly, the sub-layers 211A-211n may represent a gradient in the underlayer 210. For example, the gradient may include a change in material composition (e.g., from a high silicon percentage in sub-layer 211A to a lower silicon percentage in sub-layer 211n). The gradient may also comprise a structural gradient (e.g., from a high density in sub-layer 211A to a lower density in sub-layer 211n). Further, while discrete “layers” are shown in underlayer 210, it is to be appreciated that there may be no discernable interface between sections of the gradient in some embodiments. That is, the gradient may be a substantially continuous gradient as opposed to a gradient that is formed with a step-function approach. The gradient may approach a continuous function when the number of sub-layers 211 is increased.

In an embodiment, the gradient provided by the sub-layers 211A-211n may comprise a positive gradient or a negative gradient (from the bottom surface 216 to the top surface 217). The gradient may be a linear gradient or a non-linear gradient. In the case of a non-linear gradient the gradient may be parabolic, exponential, or the like. Other embodiments may have a gradient that increases from the bottom surface 216 until reaching a point along a thickness of the underlayer 210, and the gradient may then decrease until reaching the top surface 217. Alternatively, the gradient may decrease towards the point along the thickness of the underlayer 210, and the gradient may then increase until reaching the top surface 217.

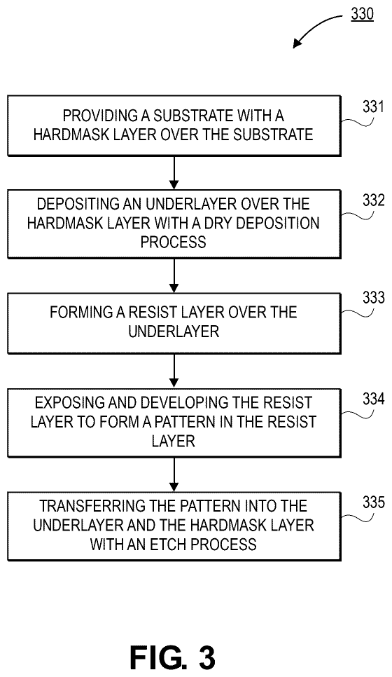

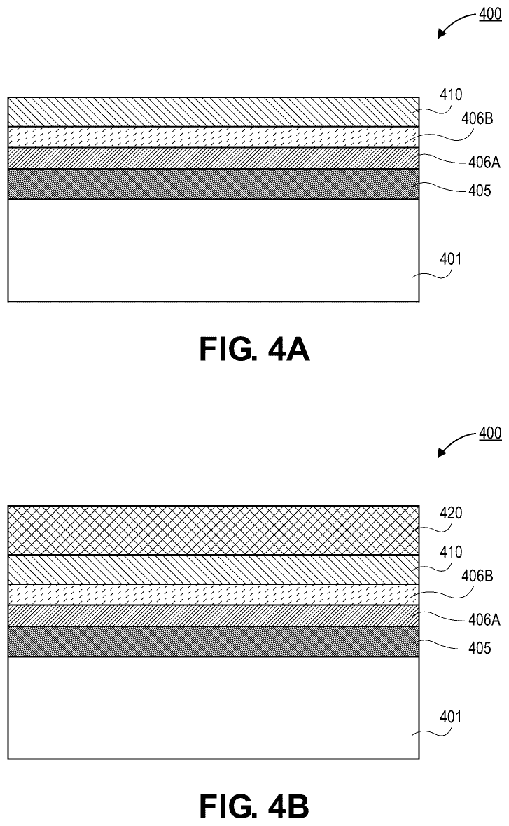

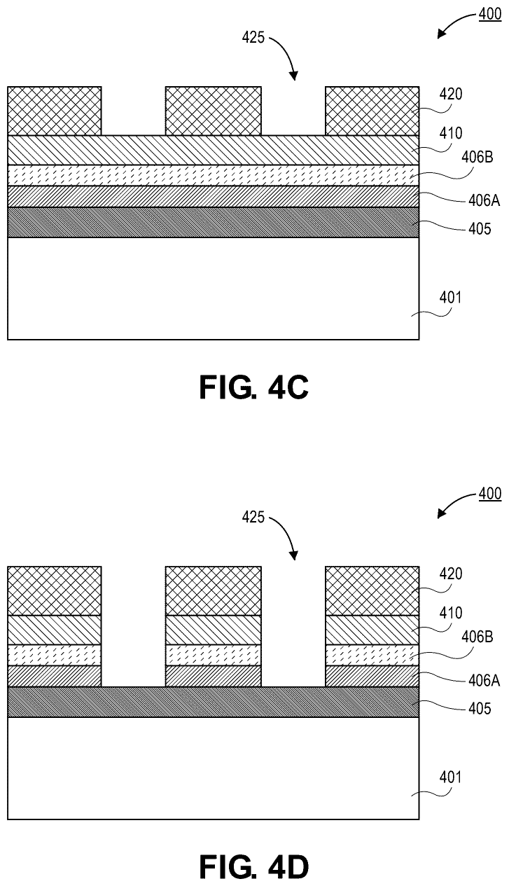

Referring now to FIG. 3, a process flow diagram of a process 330 for forming a patterning stack and developing the patterning stack is shown, in accordance with an embodiment. In an embodiment, the process 330 may be interpreted in conjunction with the Figures provided in FIGS. 4A-4D. Though, it is to be appreciated that a scope of process 330 may not be limited by a scope of FIGS. 4A-4D and the associated description. Similarly, the scope of FIGS. 4A-4D may not be limited by a scope of the description of process 330.

In an embodiment, the process 330 may begin with operation 331, which comprises providing a substrate with a hardmask layer over the substrate. Process 330 may continue with operation 332, which comprises depositing an underlayer over the hardmask layer with a dry deposition process. An example of such a substrate is shown in FIG. 4A. FIG. 4A also illustrates the underlayer after it has been deposited over the hardmask layer.

In FIG. 4A, a patterning stack 400 that comprises a substrate 401 is shown, in accordance with an embodiment. In an embodiment, the substrate 401 may be a semiconductor substrate, such as a silicon substrate. Though, any substrate 401 compatible with EUV lithography processes may be used in some embodiments.

In an embodiment, a device layer 405 may be provided over the substrate 401. The device layer 405 may comprise active devices (e.g., transistors, etc.), passive devices (e.g., capacitors, inductors, resistors, etc.), traces, vias, and/or the like. The device layer 405 may be part of a BEOL structure or a FEOL structure on the substrate 401. In some embodiments, the device layer 405 is the layer that will ultimately be patterned (e.g., etched) through the use of the EUV lithography process.

In an embodiment, a hardmask 406 is provided over the device layer 405. The hardmask 406 may include any number of layers. For example, in FIG. 4A the hardmask 406 includes a first hardmask layer 406A and a second hardmask layer 406B. The hardmask layers 406 may comprise any suitable materials and/or thicknesses, such as those described in greater detail above.

In an embodiment, the underlayer 410 may be deposited over the hardmask 406. Particularly, the dry deposition process may include a CVD process, a PE-CVD process, an ALD process, a PE-ALD process, or the like. As such, the underlayer 410 may have a controlled composition and/or structure. That is, the underlayer 410 may have a non-uniform material composition and/or structure through a thickness of the underlayer 410. In some embodiments, the underlayer 410 may be similar to any of the underlayer structures described in greater detail herein, such as, but not limited to those described with respect to FIGS. 2A-2C. The dry deposition process may also enable a thin underlayer 410, such as an underlayer 410 with a thickness of 50 nm or less, 25 nm or less, or 10 nm or less. In some embodiments, the dry deposition process may be a low temperature process. For example, a temperature (e.g., a substrate temperature) during the dry deposition process may be approximately 500° C. or less. In a particular embodiment, the temperature of the dry deposition process is between approximately 50° C. and approximately 500° C. In an embodiment, a post deposition treatment may be implemented after the dry deposition process. The post deposition treatment may comprise an ultraviolet (UV) treatment or a thermal treatment up to approximately 500° C.

In an embodiment, a post deposition treatment may also comprise a chemical treatment. A chemical treatment may be used to increase a porosity at a top surface of the underlayer 410. This can have multiple benefits. For example, the porous surface can store reactive chemicals during deposition processes (e.g., a CVD process) or during EUV exposure. These reactive chemical stores can then be released in order to improve resist contrast and/or improve imaging performance.

In an embodiment, the process 330 may continue with operation 333, which comprises forming a resist layer over the underlayer. FIG. 4B is a cross-sectional illustration of the patterning stack 400 after the resist layer 420 is deposited in accordance with operation 333. In an embodiment, the resist layer 420 may be any suitable EUV resist material. For example, the resist layer 420 may comprise a metal-oxide (e.g., tin-oxide) resist material, a CAR material, or the like.

In an embodiment, the resist layer 420 may be deposited with any suitable deposition process. In some embodiments, the resist layer 420 is deposited with a wet process (e.g., a spin coating process). Other embodiments may include depositing the resist layer 420 with a dry deposition process. The use of a dry deposition process may allow for improved control of the composition, thickness, and/or structure of the resist layer 420. Further, since a dry deposition process is also used to deposit the underlayer 410, both the underlayer 410 and the resist layer 420 may be deposited within the same processing chamber. As such, throughput improvements may be provided since there is at least one less substrate transfer that is needed to form the patterning stack 400.

In an embodiment, the process 330 may continue with operation 334, which comprises exposing and developing the resist layer to form a pattern in the resist layer. FIG. 4C is a cross-sectional illustration of the patterning stack 400 after a pattern 425 is formed in the resist layer 420 after a developing process. In an embodiment, the exposure process may include the use of a mask or reticle to selectively expose regions of the resist layer 420 to electromagnetic radiation, such as EUV electromagnetic radiation. The exposure process may result in a solubility switch in the exposed regions of the resist layer 420. In order to improve the resolution of the solubility switch, secondary electrons generated from the interaction of the electromagnetic radiation with the underlayer 410 may diffuse into the resist layer 420. Embodiments may also include the generation and/or release of chemical structures, elements, radicals and/or other species used in resist chemical reactions from the underlayer 410. These species can diffuse into the resist layer 420 during and/or after exposure in order to improve the solubility switch performance of the resist layer 420. The benefits provided by the underlayer 410 allow for lower doses to be used in the exposure operations while still maintaining high quality LER, LWR, LCDU, etc.

In an embodiment, process 330 may continue with operation 335, which comprises transferring the pattern into the underlayer and the hardmask layer with an etch process. FIG. 4D is a cross-sectional illustration of the patterning stack 400 after the pattern 425 transfer into the lower layers. In an embodiment, an etching process or the like may be used in order to remove selected portions of the underlayer 410 and the hardmask layers 406A and 406B. The transferred pattern 425 may then be used to pattern the underlying device layer 405. Though, in other embodiments, one or both of the resist layer 420 and the underlayer 410 may be removed before patterning the device layer 405.

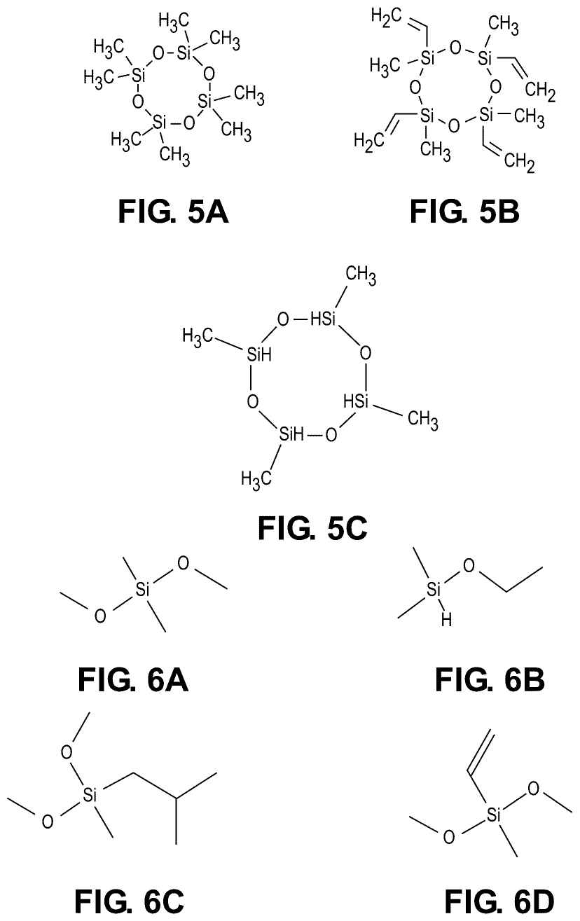

In an embodiment, the dry deposition process of the underlayer 410 may be implemented through the use of one or more precursor gasses that are flown into a chamber. Generally, the one or more precursor gasses may comprise elements that include one or more of silicon, carbon, oxygen, and hydrogen. Examples of some suitable precursor gasses are shown in FIGS. 5A-8E.

Referring now to FIGS. 5A-5C, a series of ring type precursors, such as ring type SiCO precursors, are shown, in accordance with an embodiment. The ring type precursors may comprise silicon, carbon, oxygen, and hydrogen. FIG. 5A is a diagram of octamethylcyclotetrasiloxane. FIG. 5B is a diagram of 2,4,6,8-tetramethyl-2,4,6,8tetravinylcyclotetrasiloxane. FIG. 5C is a diagram of 2,4,6,8-tetramethylcyclotetrasioloxane.

Referring now to FIGS. 6A-6D, a series of linear precursors, such as linear SiCO precursors, are shown, in accordance with an embodiment. The linear precursors may comprise silicon, oxygen, carbon, and hydrogen. FIG. 6A is a diagram of dimethyldimethoxysilane. FIG. 6B is a diagram of ethoxydimethylsilane. FIG. 6C is a diagram of isobutylmethyldimethoxysilane. FIG. 6D is a diagram of vinylmethyldimethoxysilane.

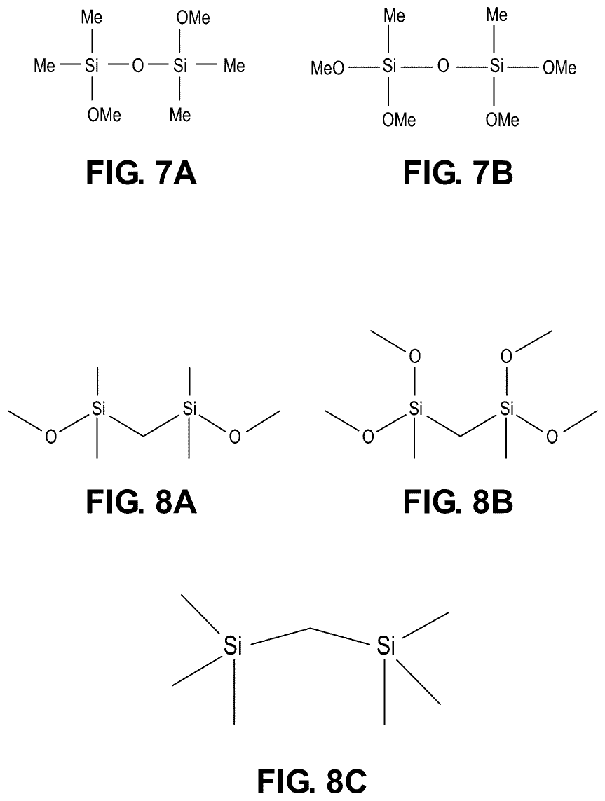

Referring now to FIGS. 7A and 7B, a pair of built in precursors comprising Si—O—Si structures is shown, in accordance with an embodiment. FIG. 7A is a diagram of 1,1,3,3,-tetramethyl-1,3-dimethoxydisiloxane. FIG. 7B is a diagram of 1,3-dimethyl-1,1,3,3-tetramethoxydisiloxane.

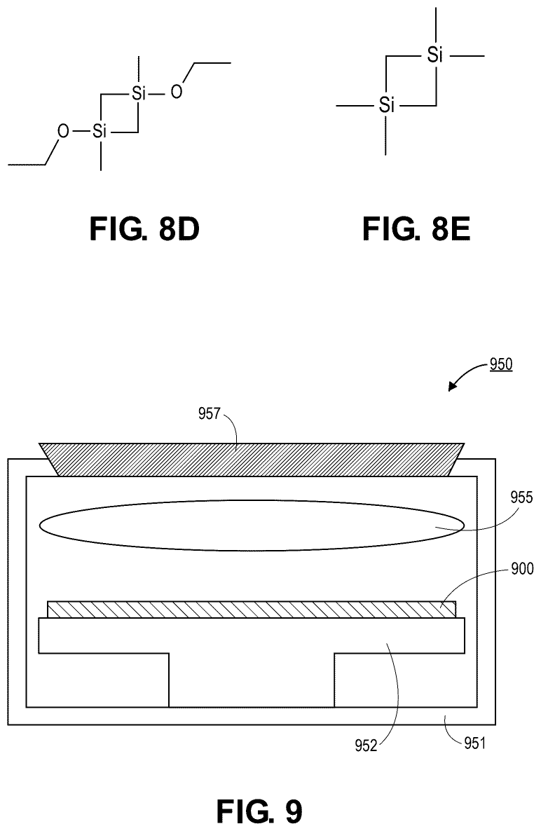

Referring now to FIGS. 8A-8E, a series of built in precursors comprising Si—C—Si structures is shown, in accordance with an embodiment. FIG. 8A is a diagram of methoxy (dimethyl) silylmethane. FIG. 8B is a diagram of methyl(dimethoxy) silylmethane. FIG. 8C is a diagram of bis(trimethylsilyl) methane. FIG. 8D is a diagram of 1,3-dimethoxy-1,3-dimethyl-1,3-disilacyclobutane (EMSCB). FIG. 8E is a diagram of 1,1,3,3-tetramethyl-1,3-disilacyclobutane.

Referring now to FIG. 9, a cross-sectional illustration of a tool 950 that may be used to deposit an underlayer for EUV lithography is shown, in accordance with an embodiment. The tool 950 may include a chamber 951 capable of supporting conditions for dry deposition processes (e.g., CVD, PE-CVD, ALD, PE-ALD, etc.). For example, the chamber 951 may be suitable for handling low pressures used to support the generation of a plasma 955. In an embodiment, a pedestal 952 for supporting a substrate 900 may be provided in the chamber 951. The pedestal 952 may include chucking capability (e.g., electrostatic chucking, etc.), temperature control (e.g., resistive heaters, backside gas channels, etc.), and the like. In an embodiment, a lid 957 may be provided above the pedestal 952 to seal the chamber 951. The lid 957 may include a showerhead (not shown) for distributing processing gasses (e.g., precursors such as those described in greater detail herein) into the chamber 951. The lid 957 may also apply an RF bias for initiating and sustaining the plasma 955.

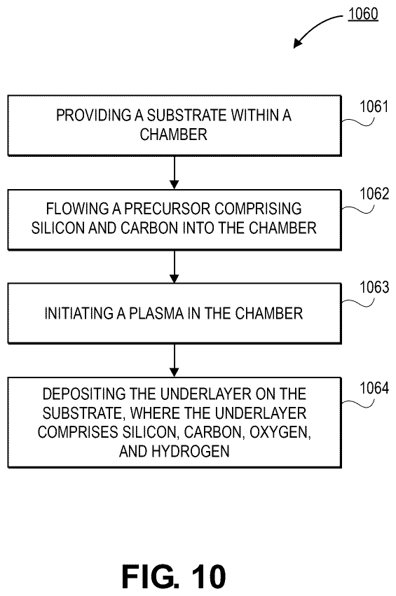

Referring now to FIG. 10, a process flow diagram of a process 1060 for depositing an underlayer for EUV lithography is shown, in accordance with an embodiment. In an embodiment, the process 1060 may begin with operation 1061, which comprises providing a substrate within a chamber. The substrate may be similar to any of the substrates described in greater detail herein. In some embodiments, the substrate may comprise a device layer and a hardmask layer over the device layer. The chamber may be a vacuum chamber. The chamber may be similar to the chamber 951 described in greater detail herein. Though, any suitable chamber for dry deposition processes may be used.

In an embodiment, process 1060 may continue with operation 1062, which comprises flowing a precursor comprising silicon and carbon into the chamber. The precursor may be similar to any of the precursors described in greater detail herein. For example, the precursor may comprise a ring-type precursor, a linear precursor, an Si—O—Si built in precursor, and/or an Si—C—Si built in precursor.

In an embodiment, the precursors may comprise silicon, carbon, and oxygen. Though, in other instances, a first precursor comprising silicon and carbon may be used in combination with a second precursor comprising oxygen (e.g., O₂ gas). The first precursor and the second precursor may both be flown into the chamber at the same time. In other embodiments, the first precursor and the second precursor may be flown into the chamber with alternating pulses.

In an embodiment, a carrier gas may also be flown into the chamber along with the one or more precursor gasses. For example, carrier gasses such as helium, nitrogen, argon, or other non-reactive gasses may be used in some embodiments. A total flowrate of the gasses (e.g., the one or more precursor gasses and the carrier gas) may be between 100 sccm and 5,000 sccm. Though, lower or higher flow rates may be used in some embodiments. Pressures within the chamber may be below 50 torr, below 25 torr, below 5 torr, or below 1 torr. Though higher pressures may also be used in some embodiments. A temperature of the substrate may be maintained between 50° C. and 500° C. Though, higher or lower temperatures may be used in some embodiments.

In an embodiment, the process 1060 may continue with operation 1063, which comprises initiating a plasma in the chamber. The plasma may be initiated during the flow of precursor into the chamber. The plasma may be initiated with any suitable frequency or plasma type, such as but not limited to, a capacitively coupled plasma (CCP), an inductively coupled plasma (ICP), a microwave plasma, a remote plasma, or the like. Any suitable RF and/or DC bias may also be applied in order to drive subsequent deposition of the underlayer. While process 1060 includes the use of a plasma, it is to be appreciated that some embodiments may not include the use of a plasma during deposition of the underlayer.

In an embodiment, the process 1060 may continue with operation 1064, which comprises depositing the underlayer on the substrate. In an embodiment, the underlayer comprises silicon, carbon, oxygen, and hydrogen. For example, the underlayer may generally be described as being a SiCHO film. Though, it is to be appreciated that the exact bonding configurations and/or concentrations of various species may be varied depending on processing conditions. For example, embodiments may include structures such as one or more of Si—C, C—H, Si—O—Si, Si—O—H, O—H, CH₃, Si-CH₂, Si—C—Si, and/or the like. The percentages of each bonding type and/or structure may be determined, at least in part, by the processing conditions selected during the process 1060.

Additionally, as described in greater detail above, the processing conditions may be modulated, varied, changed, and/or the like during a duration of the deposition process. As such, the composition and/or structure of the underlayer at a first point (in a thickness direction) may be different than the composition and/or structure of the underlayer at a second point (in the thickness direction). This may allow for the tailoring of the underlayer in order to improve EUV lithography performance, enhance adhesion, and or provide other benefits.

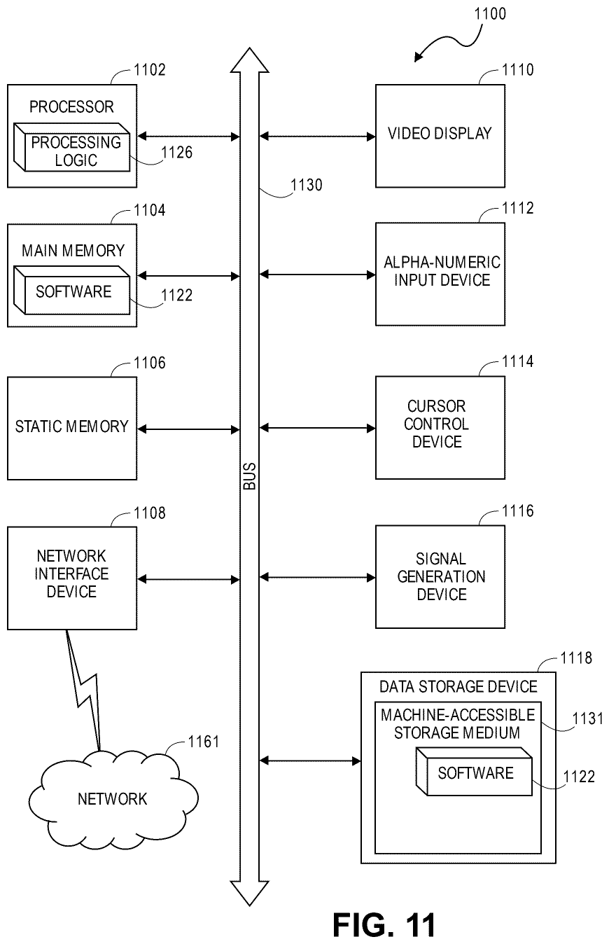

Referring now to FIG. 11, a block diagram of an exemplary computer system 1100 of a processing tool is illustrated in accordance with an embodiment. In an embodiment, computer system 1100 is coupled to and controls processing in the processing tool. Computer system 1100 may be connected (e.g., networked) to other machines in a Local Area Network (LAN), an intranet, an extranet, or the Internet. Computer system 1100 may operate in the capacity of a server or a client machine in a client-server network environment, or as a peer machine in a peer-to-peer (or distributed) network environment. Computer system 1100 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1100, the term “machine” shall also be taken to include any collection of machines (e.g., computers) that individually or jointly execute a set (or multiple sets) of instructions to perform any one or more of the methodologies described herein.

Computer system 1100 may include a computer program product, or software 1122, having a non-transitory machine-readable medium having stored thereon instructions, which may be used to program computer system 1100 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1100 includes a system processor 1102, a main memory 1104 (e.g., read-only memory (ROM), flash memory, dynamic random access memory (DRAM) such as synchronous DRAM (SDRAM) or Rambus DRAM (RDRAM), etc.), a static memory 1106 (e.g., flash memory, static random access memory (SRAM), etc.), and a secondary memory 1118 (e.g., a data storage device), which communicate with each other via a bus 1130.

System processor 1102 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1102 may also be one or more special-purpose processing devices such as an application specific integrated circuit (ASIC), a field programmable gate array (FPGA), a digital signal system processor (DSP), network system processor, or the like. System processor 1102 is configured to execute the processing logic 1126 for performing the operations described herein.

The computer system 1100 may further include a system network interface device 1108 for communicating with other devices or machines. The computer system 1100 may also include a video display unit 1110 (e.g., a liquid crystal display (LCD), a light emitting diode display (LED), or a cathode ray tube (CRT)), an alphanumeric input device 1112 (e.g., a keyboard), a cursor control device 1114 (e.g., a mouse), and a signal generation device 1116 (e.g., a speaker).

The secondary memory 1118 may include a machine-accessible storage medium 1131 (or more specifically a computer-readable storage medium) on which is stored one or more sets of instructions (e.g., software 1122) embodying any one or more of the methodologies or functions described herein. The software 1122 may also reside, completely or at least partially, within the main memory 1104 and/or within the system processor 1102 during execution thereof by the computer system 1100, the main memory 1104 and the system processor 1102 also constituting machine-readable storage media. The software 1122 may further be transmitted or received over a network 1161 via the system network interface device 1108. In an embodiment, the network interface device 1108 may operate using RF coupling, optical coupling, acoustic coupling, or inductive coupling.

While the machine-accessible storage medium 1131 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for patterning a stack, comprising:
providing a substrate with a hardmask layer over the substrate;
depositing an underlayer over the hardmask layer with a dry deposition process, wherein the underlayer comprises silicon, carbon, oxygen, and hydrogen;
forming a resist layer over the underlayer;
exposing and developing the resist layer to form a pattern in the resist layer; and
transferring the pattern into the underlayer and the hardmask layer with an etch process.

2. The method of claim 1, wherein the underlayer comprises a first sub-layer on the hardmask layer and a second sub-layer over the first sub-layer.

3. The method of claim 2, wherein the first sub-layer has a first silicon concentration, and wherein the second sub-layer has a second silicon concentration that is different than the first silicon concentration.

4. The method of claim 1, wherein the underlayer has a compositional gradient between a bottom surface and a top surface.

5. The method of claim 1, wherein the dry deposition process is a chemical vapor deposition (CVD) processor an atomic layer deposition (ALD) process.

6. The method of claim 1, wherein the dry deposition process is implemented at a temperature of 500° C. or lower.

7. The method of claim 1, wherein the dry deposition process comprises using a plasma.

8. The method of claim 1, wherein the dry deposition process comprises flowing one or more of a ring type SiCO precursor, a linear SiCO precursor, a built in Si—O—Si SiCO precursor, or a built in Si—C—Si SiCO precursor.

9. The method of claim 1, wherein the resist layer is an extreme ultraviolet (EUV) resist.

10. The method of claim 1, further comprising a post deposition treatment after the dry deposition process, wherein the post deposition treatment is a UV cure or a thermal cure at a temperature up to 500° C., or wherein the post deposition treatment is a chemical treatment, and wherein the post deposition treatment increases a porosity of a top surface of the underlayer.

11. A method for forming an underlayer for extreme ultraviolet (EUV) lithography, comprising:
providing a substrate within a chamber;
flowing a precursor comprising silicon and carbon into the chamber;
initiating a plasma in the chamber; and
depositing the underlayer on the substrate, wherein the underlayer comprises silicon, carbon, oxygen, and hydrogen.

12. The method of claim 11, wherein one or more deposition parameters are varied during a duration of depositing the underlayer on the substrate.

13. The method of claim 12, wherein the one or more deposition parameters that are varied may comprise one or more of, a substrate temperature, a pressure in the chamber, a flowrate of the precursor, a chemical composition of the precursor, a flowrate of a carrier gas, a flowrate of oxygen, or a bias potential.

14. The method of claim 11, wherein a thickness of the underlayer is 50 nm or less.

15. The method of claim 11, further comprising:
flowing a second precursor into the chamber, wherein the second precursor comprises oxygen.

16. The method of claim 11, wherein the method is a plasma-enhanced chemical vapor deposition (PE-CVD) process or a plasma-enhanced atomic layer deposition (PE-ALD) process.

17. An underlayer, comprising:
a dielectric material with a top surface and a bottom surface, wherein the dielectric material comprises silicon, carbon, hydrogen, and oxygen; and
two or more sub-layers within the dielectric material, wherein the two or more sub-layers comprise different concentrations of one or more of silicon, carbon hydrogen, and oxygen.

18. The underlayer of claim 17, wherein a first sub-layer is at the bottom surface and a second sub-layer is at the top surface, and wherein a thickness of the second sub-layer is greater than a thickness of the first sub-layer.

19. The underlayer of claim 17, wherein a thickness of the dielectric material is 50 nm or less.

20. The underlayer of claim 17, wherein the underlayer is configured for use in extreme ultraviolet (EUV) lithography.
